(19) United States
(12) Patent Application Publication
(10) Pub. No.: US 2024/0072194 A1
(43) Pub. Date: Feb. 29, 2024

(54) LIGHT-RECEIVING DEVICE AND RECEIVING DEVICE

(71) Applicant: NEC CORPORATION, Minato-ku, Tokyo (JP)

(72) Inventors: Koya Takata, Tokyo (JP); Hisashi MIZUMOTO, Tokyo (JP); Fujio OKUMURA, Kanagawa (JP)

(73) Assignee: NEC Corporation, Minato-ku, Tokyo (JP)

(21) Appl. No.: 18/270,660

(22) PCT Filed: Oct. 25, 2021
(86) PCT No.: PCT/JP2021/039349

§ 371 Date: Jun. 30, 2023

(30) Foreign Application Priority Data
Jan. 6, 2021 (JP) 2021-000636

(51) Int. Cl. H01L 31/167; H01L 31/0232

(52) U.S. Cl. CPC H01L 31/167; H01L 31/02327; H04B 10/67

(57) ABSTRACT

Please delete the Abstract of the Disclosure, and replace it with the following: A light-receiving device that includes a substrate which transmits light in the wavelength band of a spatial light signal to be received, an optical antenna which is disposed on a first surface of the substrate, which receives the spatial light signal, which optically guides signal light derived from the spatial light signal along the in-plane direction of the substrate toward an emission end, and which outputs the signal light from the emission end toward the substrate, and a light-receiving element which is disposed such that a light-receiving surface faces a second surface of the substrate opposite from the first surface, and which receives, at the light-receiving surface, the signal light output from the optical antenna.

### TECHNICAL FIELD

The present disclosure relates to a light-receiving device or the like that receives a spatial light signal.

### BACKGROUND ART

In optical spatial communication, signal light (hereinafter, also referred to as a spatial light signal) propagating in space is transmitted and received without using a medium such as an optical fiber. In order to receive a spatial light signal that spreads and propagates in a space, a condensing lens as large as possible is required. In optical spatial communication, a photodiode having a small capacitance is used to perform high-speed communication. Since such a photodiode has a very small light-receiving surface, it is difficult for the condensing lens to condense spatial light signals arriving from various directions toward the light-receiving surface.

PTL 1 discloses a light-receiving element that converts incident light into surface plasmon and receives the surface plasmon. The light-receiving element of PTL 1 includes a conductive thin film and a light-receiving portion. A coupling periodic structure for converting incident light into surface plasmon is formed on the surface of the conductive thin film. In the coupling periodic structure, an opening penetrating the front and back surfaces of the conductive thin film is formed. The light-receiving portion is disposed at an end portion of a surface opposite to a surface on which the coupling periodic structure of the opening is formed.

NPL 1 and NPL 2 disclose light detection and ranging (LiDAR) using a waveguide grating antenna (WGA) and a communication device. The WGA disclosed in NPLs 1 and 2 functions as an optical antenna exhibiting strong directivity and also functions as a light guide.

### CITATION LIST

### Patent Literature

PTL 1: JP 2007-248141 A

### Non Patent Literature

NPL 1: M. Raval, et. al., “Unidirectional waveguide grating antennas with uniform emission for optical phased arrays”, Optics Letters, Vol. 42, No. 13, Jul. 1, 2017, pp. 2563-2566.
NPL 2: C. Poulton, et. al., “Long-Range LiDAR and Free-Space Data Communication With High-Performance Optical Phased Arrays”, IEEE JOURNAL OF SELECTED TOPICS IN QUANTUM ELECTRONICS, VOL. 25, NO. 5, SEPTEMBER/OCTOBER 2019.

### SUMMARY OF INVENTION

### Technical Problem

The light-receiving element of PTL 1 can obtain high-speed responsiveness by receiving incident light converted into surface plasmon in the coupling periodic structure by the light-receiving portion through an opening having a small opening area. The light-receiving element of PTL 1 can be applied to optical wiring of a large-scale integrated circuit. However, it has been difficult for the light-receiving element of PTL 1 to be large enough to be used for receiving a spatial light signal.

An object of the present disclosure is to provide a light-receiving device and the like that can efficiently receive a spatial light signal.

### Solution to Problem

A light-receiving device according to one aspect of the present disclosure includes a substrate which transmits light in the wavelength band of a spatial light signal to be received, an optical antenna which is disposed on a first surface of the substrate, which receives the spatial light signal, which optically guides signal light derived from the spatial light signal along the in-plane direction of the substrate toward an emission end, and which outputs the signal light from the emission end toward the substrate, and a light-receiving element which is disposed such that a light-receiving surface faces a second surface of the substrate opposite from the first surface, and which receives, at the light-receiving surface, the signal light output from the optical antenna.

### Advantageous Effects of Invention

According to the present disclosure, it is possible to provide a light-receiving device and the like capable of efficiently receiving a spatial light signal.

### BRIEF DESCRIPTION OF DRAWINGS

FIG. 1 is a plan view illustrating an example of a conceptual configuration of a light-receiving device according to a first example embodiment.

FIG. 2 is a cross-sectional view illustrating an example of a conceptual configuration of the light-receiving device according to the first example embodiment.

FIG. 3 is a cross-sectional view illustrating an example of a conceptual configuration of the light-receiving device according to the first example embodiment.

FIG. 4 is a plan view illustrating an example of a conceptual configuration of a light-receiving device of a first modification example according to the first example embodiment.

FIG. 5 is a plan view illustrating an example of a conceptual configuration of a light-receiving device of a second modification example according to the first example embodiment.

FIG. 6 is a plan view illustrating an example of a conceptual configuration of a light-receiving device of a third modification example according to the first example embodiment.

FIG. 7 is a plan view illustrating an example of a conceptual configuration of a light-receiving device of a fourth modification example according to the first example embodiment.

FIG. 8 is a plan view illustrating an example of a conceptual configuration of a light-receiving device of a fifth modification example according to the first example embodiment.

FIG. 9 is a plan view illustrating an example of a conceptual configuration of a light-receiving device of a sixth modification example according to the first example embodiment.

FIG. 10 is a plan view illustrating an example of a conceptual configuration of a light-receiving device of a seventh modification example according to the first example embodiment.

FIG. 11 is a plan view illustrating an example of a conceptual configuration of a light-receiving device of an eighth modification example according to the first example embodiment.

FIG. 12 is a plan view illustrating an example of a conceptual configuration of a light-receiving device according to a second example embodiment.

FIG. 13 is a cross-sectional view illustrating an example of a conceptual configuration of the light-receiving device according to the second example embodiment.

FIG. 14 is a plan view illustrating an example of a conceptual configuration of a light-receiving device according to a third example embodiment.

FIG. 15 is a cross-sectional view illustrating an example of a conceptual configuration of the light-receiving device according to the third example embodiment.

FIG. 16 is a plan view illustrating an example of a conceptual configuration of a light-receiving device according to a fourth example embodiment.

FIG. 17 is a cross-sectional view illustrating an example of a conceptual configuration of the light-receiving device according to the fourth example embodiment.

FIG. 18 is a plan view illustrating an example of a conceptual configuration of a light-receiving device according to a fifth example embodiment.

FIG. 19 is a cross-sectional view illustrating an example of a conceptual configuration of the light-receiving device according to the fifth example embodiment.

FIG. 20 is a conceptual diagram for explaining an example of phase adjustment by a phase shifter of the light-receiving device according to the fifth example embodiment.

FIG. 21 is a conceptual diagram for explaining another example of phase adjustment by the phase shifter of the light-receiving device according to the fifth example embodiment.

FIG. 22 is a cross-sectional view illustrating an example of a conceptual configuration of a light-receiving device of a ninth modification example according to the fifth example embodiment.

FIG. 23 is a conceptual diagram illustrating an example of a configuration of a light-receiving device according to a sixth example embodiment.

FIG. 24 is a block diagram illustrating an example of a configuration of a receiving device according to a seventh example embodiment.

FIG. 25 is a plan view illustrating an example of a conceptual configuration of a light-receiving device according to an eighth example embodiment.

FIG. 26 is a cross-sectional view illustrating an example of a conceptual configuration of the light-receiving device according to the eighth example embodiment.

### EXAMPLE EMBODIMENT

Hereinafter, example embodiments of the present invention will be described with reference to the drawings. However, the example embodiments described below may be technically limited for carrying out the present invention, but the scope of the invention is not limited to the following. In all the drawings used in the following description of the example embodiment, the same reference numerals are given to the same parts unless there is a particular reason. In the following example embodiments, repeated description of similar configurations and operations may be omitted.

A line indicating a trajectory of light in the drawings relating to the following example embodiments is conceptual, and does not accurately indicate an actual traveling direction or state of light. For example, in the drawings relating to the following example embodiments, a change in a traveling direction or a state of light due to refraction, reflection, diffusion, or the like at an interface between air and a substance may be omitted, or a light flux may be expressed by one line.

### First Example Embodiment

First, a light-receiving device according to a first example embodiment will be described with reference to the drawings. The light-receiving device of the present example embodiment is used for optical spatial communication in which signal light beams (hereinafter, also referred to as a spatial light signal) propagating in a space are transmitted and received. The light-receiving device of the present example embodiment may be applied to applications other than optical spatial communication as long as the light-receiving device receives light propagating in a space. Hereinafter, the spatial light signal is regarded as parallel light in order to arrive from a sufficiently distant position.

(Configuration)

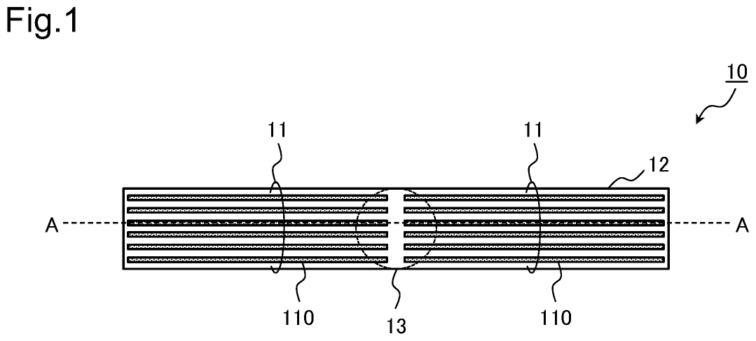

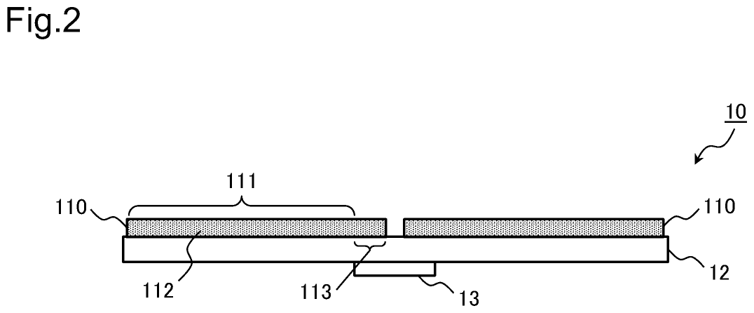

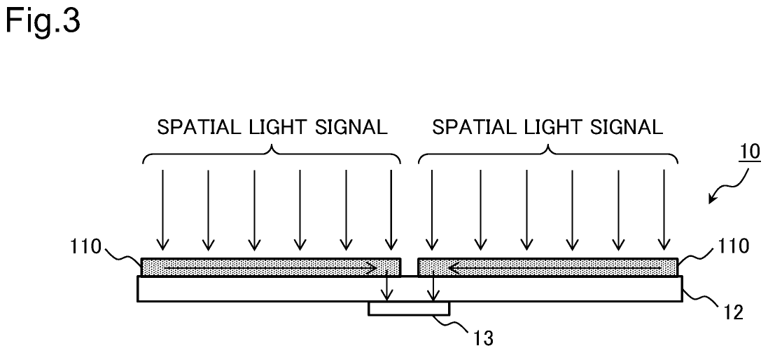

FIG. 1 is a plan view illustrating an example of a configuration of a light-receiving device 10 of the present example embodiment. FIGS. 2 and 3 are cross-sectional views of the light-receiving device 10 taken along line A-A in FIG. 1. FIG. 3 conceptually illustrates a trajectory of a spatial light signal incident on the light-receiving device 10 and light traveling inside the light-receiving device 10 by an arrow. The light-receiving device 10 includes an optical antenna 11, a substrate 12, and a light-receiving element 13. FIGS. 1 to 3 illustrate the light-receiving device 10 including two sets of optical antennas 11. In FIG. 1, the position of the light-receiving element 13 disposed on the back surface (second surface) of the substrate 12 is indicated by a dotted line.

The optical antenna 11 is formed on the surface (hereinafter, also referred to as a first surface) of the substrate 12. The optical antenna 11 includes a plurality of waveguide pipes 110. The plurality of waveguide pipes 110 may have the same length so that phases of light received by the light-receiving element 13 are aligned. The waveguide pipe 110 includes a light-receiving portion 111, a light guide path 112, and an emission end 113. The light-receiving portion 111 is formed on a side surface of the waveguide pipe 110. The light-receiving portion 111 is directed in the out-of-plane direction of a first surface of the substrate 12. The light-receiving portion 111 receives light in the wavelength band of the spatial light signal. The light guide path 112 is formed inside the waveguide pipe 110. The light guide path 112 guides light (also referred to as signal light) derived from the spatial light signal to the emission end 113 along the in-plane direction of the substrate 12. The emission end 113 is formed on a side surface on an opposite side of the light-receiving portion 111 among side surfaces close to one end portion of the waveguide pipe 110. The emission end 113 is disposed toward the first surface of the substrate 12. The emission end 113 is disposed toward the light-receiving surface of the light-receiving element 13 with the substrate 12 interposed therebetween. The light received by the light-receiving portion 111 is guided toward the emission end 113 through the light guide path 112. The light guided through the light guide path 112 is emitted from the emission end 113 toward the light-receiving portion of the light-receiving element 13.

For example, the optical antenna 11 is realized by a waveguide grating antenna (WGA) disclosed in NPLs 1 and 2 (NPL 1: M. Raval, et. al., “Unidirectional waveguide grating antennas with uniform emission for optical phased arrays”, Optics Letters, Vol. 42, No. 13, Jul. 1, 2017, pp. 2563-2566., NPL 2: C. Poulton, et. al., “Long-Range LiDAR and Free-Space Data Communication With High-Performance Optical Phased Arrays”, IEEE JOURNAL OF SELECTED TOPICSIN QUANTUM ELECTRONICS, VOL. 25, NO. 5, SEPTEMBER/OCTOBER 2019.).

The WGA functions as an optical antenna exhibiting strong directivity and also functions as a light guide. NPLs 1 and 2 disclose a WGA including two silicon nitride layers inside a silicon oxide layer on a silicon substrate. The two silicon nitride layers are formed with a constant gap. Etched regions (perturbation regions) are periodically formed in the two silicon nitride layers. The WGA is formed by patterning a perturbation region in two silicon nitride layers inside the waveguide pipe. Four patterns (patterns 1 to 4) are formed inside the waveguide pipe as viewed from above. In the pattern 1, unetched regions (full width regions) overlap each other. In the pattern 2, the perturbation region and the full width region overlap. In the pattern 3, the perturbation regions overlap each other. In the pattern 4, the full width region and the perturbation region overlap. The pattern 2 and the pattern 4 are substantially the same pattern. These patterns provide a unidirectional emitter with two scattering elements of ¼ wavelength in displacement that produce constructive interference in one direction and destructive interference in the other direction, both in directions perpendicular and horizontal to the horizontal plane of the silicon substrate.

For example, the optical antenna 11 can be realized by WGA. In this case, the optical antenna 11 may be configured to generate constructive interference between the inside of the light guide path 112 and the emission end 113 in directions orthogonal to each other. According to this configuration, the traveling direction of the light guided in the extending direction of the light guide path 112 can be changed to the direction of the light-receiving surface of the light-receiving element 13 at the emission end 113.

The substrate 12 has a rectangular shape in plan view. The waveguide pipe 110 is disposed on the first surface of the substrate 12. The light-receiving element 13 is disposed on the second surface facing the first surface of the substrate 12. The substrate 12 transmits light in the wavelength band of the spatial light signal. For example, the substrate 12 is a substrate made of silicon (Si). The substrate 12 made of Si has high transmittance of light in an infrared region. Therefore, when the wavelength band of the spatial light signal is in the infrared region, the light emitted from the emission end 113 of the waveguide pipe 110 is transmitted through the substrate 12 and received by the light-receiving surface of the light-receiving element 13. The material of the substrate 12 may be selected according to the wavelength band of the spatial light signal used for spatial light communication. If the wavelength band of the spatial light signal is visible light, the substrate 12 such as glass or plastic may be used.

The light-receiving element 13 is disposed on the second surface of the substrate 12. The light-receiving element 13 is disposed near the center of the substrate 12. The light-receiving element 13 has a light-receiving surface that receives light in the wavelength band of the spatial light signal. The light-receiving element 13 is disposed such that its light-receiving surface faces the emission end 113 of the waveguide pipe 110 via the substrate 12. The light emitted from the emission end 113 of the waveguide pipe 110 is transmitted through the substrate 12 and received by the light-receiving surface of the light-receiving element 13.

The light-receiving element 13 receives light in a wavelength region of the spatial light signal to be received. For example, the light-receiving element 13 receives signal light in an infrared region. The light-receiving element 13 receives signal light having a wavelength in a 1.5 μm band, for example. The wavelength band of the signal light received by the light-receiving element 13 is not limited to the 1.5 μm band. The wavelength band of the signal light received by the light-receiving element 13 can be arbitrarily set in accordance with the wavelength of the spatial light signal. The wavelength band of the signal light received by the light-receiving element 13 may be set to, for example, a 0.8 μm band, a 1.55 μm band, or a 2.2 μm band. The wavelength band of the signal light received by the light-receiving element 13 may be, for example, a 0.8 μm to 1 μm band. When the wavelength band of the signal light is short, absorption by moisture in the atmosphere is small, which is advantageous for optical spatial communication during rainfall. The light-receiving element 13 may receive signal light in the visible region. If the light-receiving element 13 is saturated with intense sunlight, the signal light derived from the spatial light signal cannot be read. Therefore, a color filter that selectively passes the light in the wavelength band of the spatial light signal may be installed in the preceding stage of the light-receiving element 13.

The light-receiving element 13 converts the received signal light into an electric signal. The light-receiving element 13 outputs the converted electric signal to a decoder (not illustrated). For example, the light-receiving element 13 can be realized by an element such as a photodiode or a phototransistor. For example, the light-receiving element 13 is realized by an avalanche photodiode. The light-receiving element 13 realized by the avalanche photodiode can support high-speed communication. The light-receiving element 13 may be realized by an element other than a photodiode, a phototransistor, or an avalanche photodiode as long as signal light can be converted into an electrical signal.

The light-receiving surface of the light-receiving element 13 may be as small as possible in order to improve the communication speed. For example, the light-receiving surface of the light-receiving element 13 has a light-receiving surface having a diameter of about 0.1 mm to 0.3 mm (millimeter). Although the light condensed by the condensing lens or the like is condensed within a certain range depending on the arrival direction of the spatial light signal, it is difficult to condense the light on the region where the light-receiving surface of the light-receiving element 13 is disposed. In the present example embodiment, the optical antenna 11 that functions as an optical antenna exhibiting strong directivity and also functions as a light guide is used. The optical antenna 11 guides light derived from spatial light signals arriving from various directions to the light-receiving surface of the light-receiving element 13. The light derived from the spatial light signal received by the light-receiving portion 111 of the optical antenna 11 is emitted from the emission end 113 facing the light-receiving surface of the light-receiving element 13 via the light guide path 112. Therefore, the light-receiving device 10 can efficiently guide the spatial light signal arriving from an arbitrary direction to the light-receiving surface of the light-receiving element 13.

### Modification Example

Next, a modification example of the light-receiving device 10 of the present example embodiment will be described with reference to the drawings. Hereinafter, a description will be given using a plan view of a modification example of the light-receiving device 10. In the following modification example, the optical antenna 11 and the substrate 12 different from the configuration of the light-receiving device 10 in FIGS. 1 to 3 are included, but they may be denoted by the same reference numerals as those of the light-receiving device 10. In the following modification example, an example in which a plurality of waveguide pipes 110 having different extending directions are disposed on the same substrate 12 will be described. If the extending direction of the waveguide pipe 110 is different, the phase of the signal light emitted to the light-receiving surface of the light-receiving element 13 is different according to the arrival direction of the spatial light signal. However, in the following modification example, the phase shift of the light is ignored.

### First Modification Example

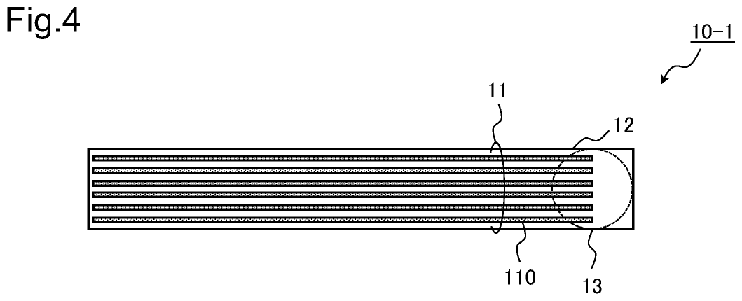

FIG. 4 is a plan view illustrating an example of a configuration of a light-receiving device 10-1 of a first modification example. The substrate 12 has a rectangular shape in plan view. The light-receiving device 10-1 includes one light-receiving element 13. The light-receiving element 13 is disposed at a position indicated by a dotted circle at a right end of the second surface of the substrate 12.

The light-receiving device 10-1 includes a set of optical antennas 11. Emission ends of the plurality of waveguide pipes 110 constituting the optical antenna 11 are disposed at positions close to the right end of the substrate 12 so as to face the light-receiving surface of the light-receiving element 13. The light-receiving surface of the light-receiving element 13 is disposed so as to face the emission ends of the plurality of waveguide pipes 110 constituting the optical antenna 11 with the substrate 12 interposed therebetween.

According to the present modification example, similarly to the light-receiving device 10 of FIGS. 1 to 3, the light received by the optical antenna 11 can be guided to the light-receiving surface of the single light-receiving element 13.

### Second Modification Example

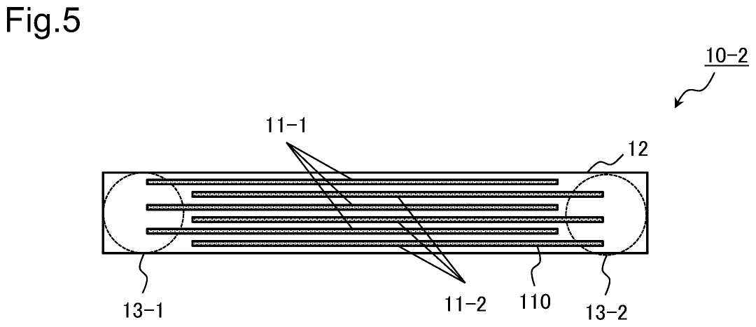

FIG. 5 is a plan view illustrating an example of a configuration of a light-receiving device 10-2 of a second modification example. The substrate 12 has a rectangular shape in plan view. The light-receiving device 10-2 includes two light-receiving elements 13 (light-receiving elements 13-1 to 13-2). The light-receiving element 13-1 is disposed at a position indicated by a dotted circle at the left end of the second surface of the substrate 12. The light-receiving element 13-2 is disposed at a position indicated by a dotted circle at the right end of the second surface of the substrate 12.

The light-receiving device 10-2 includes two sets of optical antennas 11 (optical antennas 11-1 to 11-2). The optical antenna 11-1 is disposed such that the emission ends of the plurality of waveguide pipes 110 face the light-receiving surface of the light-receiving element 13-1. The optical antenna 11-2 is disposed such that the emission ends of the plurality of waveguide pipes 110 face the light-receiving surface of the light-receiving element 13-2.

The light-receiving surface of the light-receiving element 13-1 is disposed so as to face the emission ends of the plurality of waveguide pipes 110 constituting the optical antenna 11-1 with the substrate 12 interposed therebetween. The light-receiving surface of the light-receiving element 13-2 is disposed so as to face the emission ends of the plurality of waveguide pipes 110 constituting the optical antenna 11-2 with the substrate 12 interposed therebetween.

According to the present modification example, the light received by each of the two sets of optical antennas 11 formed on the first surface of the substrate 12 can be guided to the light-receiving surface of the different light-receiving element 13.

### Third Modification Example

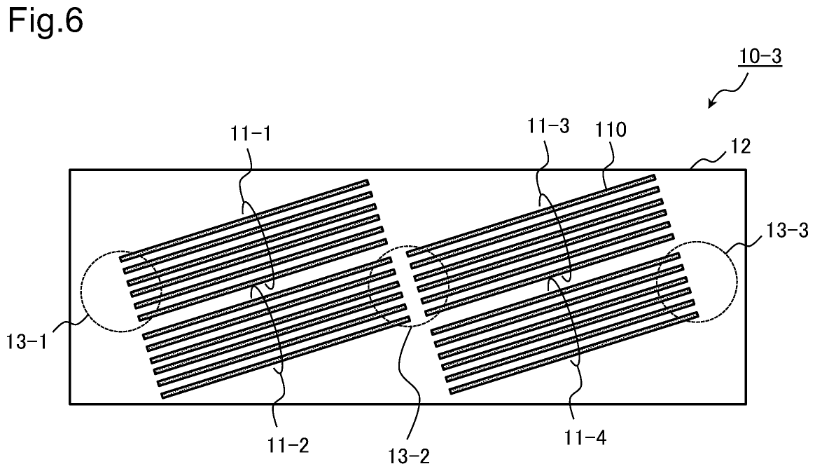

FIG. 6 is a plan view illustrating an example of a configuration of a light-receiving device 10-3 of a third modification example. The substrate 12 has a rectangular shape in plan view. The light-receiving device 10-3 includes three light-receiving elements 13 (light-receiving elements 13-1 to 13-3). The light-receiving element 13-1 is disposed at a position indicated by a dotted circle at the left end of the second surface of the substrate 12. The light-receiving element 13-2 is disposed at a position indicated by a dotted circle at the center of the second surface of the substrate 12. The light-receiving element 13-3 is disposed at a position indicated by a dotted circle at the right end of the second surface of the substrate 12.

The light-receiving device 10-3 includes four sets of optical antennas 11 (optical antennas 11-1 to 11-4). The optical antennas 11-1 to 11-4 are disposed such that the extending direction of the waveguide pipes is oblique to the longitudinal direction of the substrate 12. The optical antenna 11-1 is disposed such that the emission ends of the plurality of waveguide pipes 110 face the light-receiving surface of the light-receiving element 13-1. The optical antenna 11-2 is disposed such that the emission ends of the plurality of waveguide pipes 110 face the light-receiving surface of the light-receiving element 13-2. The optical antenna 11-3 is disposed such that the emission ends of the plurality of waveguide pipes 110 face the light-receiving surface of the light-receiving element 13-2. The optical antenna 11-4 is disposed such that the emission ends of the plurality of waveguide pipes 110 face the light-receiving surface of the light-receiving element 13-3.

The light-receiving surface of the light-receiving element 13-1 is disposed so as to face the emission ends of the plurality of waveguide pipes 110 constituting the optical antenna 11-1 with the substrate 12 interposed therebetween. The light-receiving surface of the light-receiving element 13-2 is disposed so as to face the emission ends of the plurality of waveguide pipes 110 constituting the optical antennas 11-2 and 11-3 with the substrate 12 interposed therebetween. The light-receiving surface of the light-receiving element 13-3 is disposed so as to face the emission ends of the plurality of waveguide pipes 110 constituting the optical antenna 11-4 with the substrate 12 interposed therebetween.

According to the present modification example, the light received by each of the plurality of optical antennas 11 formed on the first surface of the substrate 12 can be guided to any light-receiving surface of the plurality of light-receiving elements 13.

### Fourth Modification Example

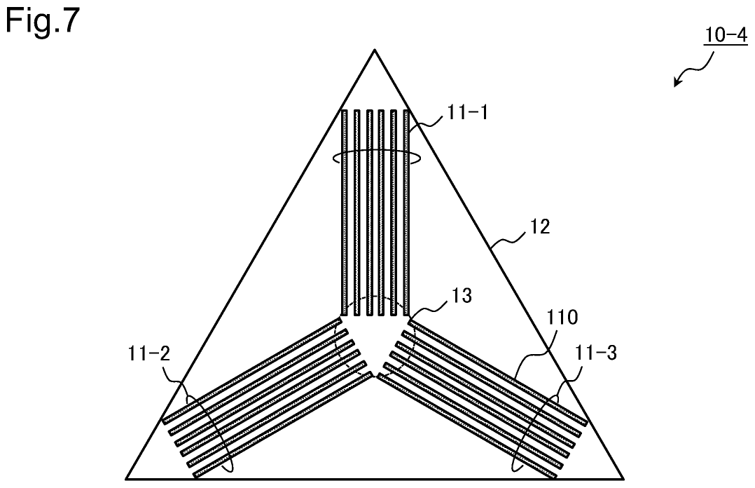

FIG. 7 is a plan view illustrating an example of a configuration of a light-receiving device 10-4 of a fourth modification example. The substrate 12 has a triangular shape in plan view. The light-receiving device 10-4 includes one light-receiving element 13. The light-receiving element 13 is disposed at a position indicated by a dotted circle including the center of gravity of the triangular substrate 12.

The light-receiving device 10-4 includes three sets of optical antennas 11 (optical antennas 11-1 to 11-3). The optical antennas 11-1 to 11-3 are disposed such that the emission ends of the plurality of waveguide pipes 110 face the light-receiving surface of the light-receiving element 13. In the optical antennas 11-1 to 11-3, end portions opposite to the emission ends of the plurality of waveguide pipes 110 are disposed toward any vertex of the triangular substrate 12. The light-receiving surface of the light-receiving element 13 is disposed so as to face the emission ends of the plurality of waveguide pipes 110 constituting the optical antennas 11-1 to 11-3 with the substrate 12 interposed therebetween.

According to the present modification example, the light received by each of the three sets of optical antennas 11 formed on the first surface of the triangular substrate 12 can be guided to the light-receiving surface of the single light-receiving element 13.

### Fifth Modification Example

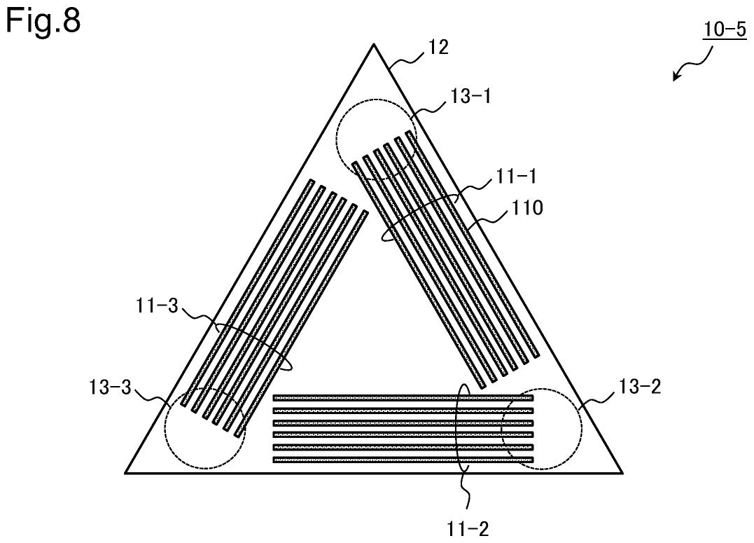

FIG. 8 is a plan view illustrating an example of a configuration of a light-receiving device 10-5 of a fifth modification example. The substrate 12 has a triangular shape in plan view. The light-receiving device 10-5 includes three light-receiving elements 13 (13-1 to 13-3). Each of the light-receiving elements 13-1 to 13-3 is disposed at a position indicated by a dotted circle in the vicinity of the vertex of the triangular substrate 12.

The light-receiving device 10-5 includes three sets of optical antennas 11 (optical antennas 11-1 to 11-3). The optical antenna 11-1 is disposed such that the extending direction of the waveguide pipe 110 is parallel to the right side of the triangular substrate 12, and the emission ends of the plurality of waveguide pipes 110 face the light-receiving surface of the light-receiving element 13-1. The optical antenna 11-2 is disposed such that the extending direction of the waveguide pipe 110 is parallel to the lower side of the triangular substrate 12, and the emission ends of the plurality of waveguide pipes 110 face the light-receiving surface of the light-receiving element 13-2. The optical antenna 11-3 is disposed such that the extending direction of the waveguide pipe 110 is parallel to the left side of the triangular substrate 12, and the emission ends of the plurality of waveguide pipes 110 face the light-receiving surface of the light-receiving element 13-3.

The light-receiving surface of the light-receiving element 13-1 is disposed so as to face the emission ends of the plurality of waveguide pipes 110 constituting the optical antenna 11-1 with the substrate 12 interposed therebetween. The light-receiving surface of the light-receiving element 13-2 is disposed so as to face the emission ends of the plurality of waveguide pipes 110 constituting the optical antenna 11-2 with the substrate 12 interposed therebetween. The light-receiving surface of the light-receiving element 13-3 is disposed so as to face the emission ends of the plurality of waveguide pipes 110 constituting the optical antenna 11-3 with the substrate 12 interposed therebetween.

According to the present modification example, the light received by each of the three sets of optical antennas 11 formed on the first surface of the triangular substrate 12 can be guided to the light-receiving surfaces of the different light-receiving elements 13.

### Sixth Modification Example

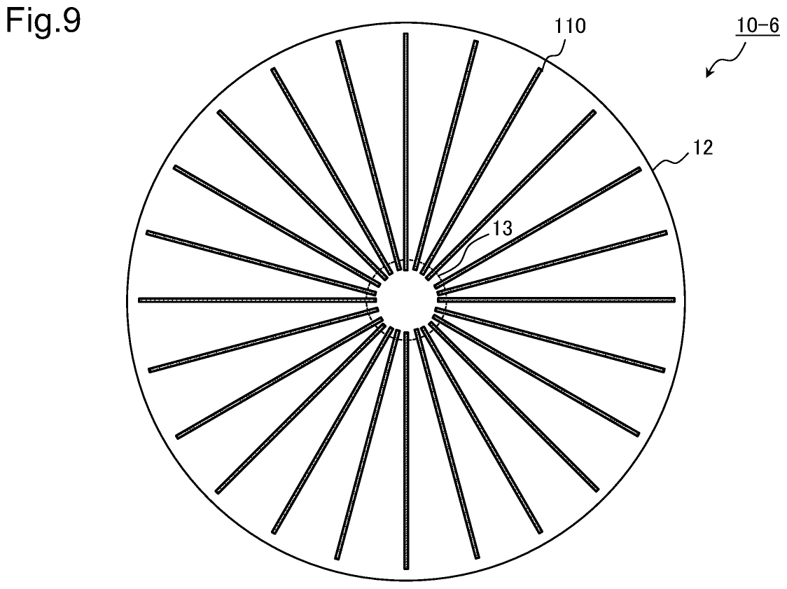

FIG. 9 is a plan view illustrating an example of a configuration of a light-receiving device 10-6 of a sixth modification example. The substrate 12 has a circular shape in plan view. The light-receiving device 10-6 includes one light-receiving element 13. The light-receiving element 13 is disposed at a position indicated by a dotted circle including the center of the circular substrate 12.

The light-receiving device 10-6 includes an optical antenna (reference numerals are omitted) including a plurality of waveguide pipes 110 radially extending in the radial direction from the vicinity of the center of the circular substrate 12. Emission ends of the plurality of waveguide pipes 110 constituting the optical antenna are disposed so as to face the light-receiving surface of the light-receiving element 13 located near the center of the circular substrate. The end portions of the plurality of waveguide pipes 110 on the side opposite to the emission ends are disposed in the radial direction of the circular substrate 12. The light-receiving surface of the light-receiving element 13 is disposed so as to face the emission ends of the plurality of waveguide pipes 110 constituting the optical antenna with the substrate 12 interposed therebetween.

According to the present modification example, the light received by the optical antenna including the plurality of waveguide pipes 110 radially formed on the first surface of the circular substrate 12 can be guided to the light-receiving surface of the single light-receiving element 13.

### Seventh Modification Example

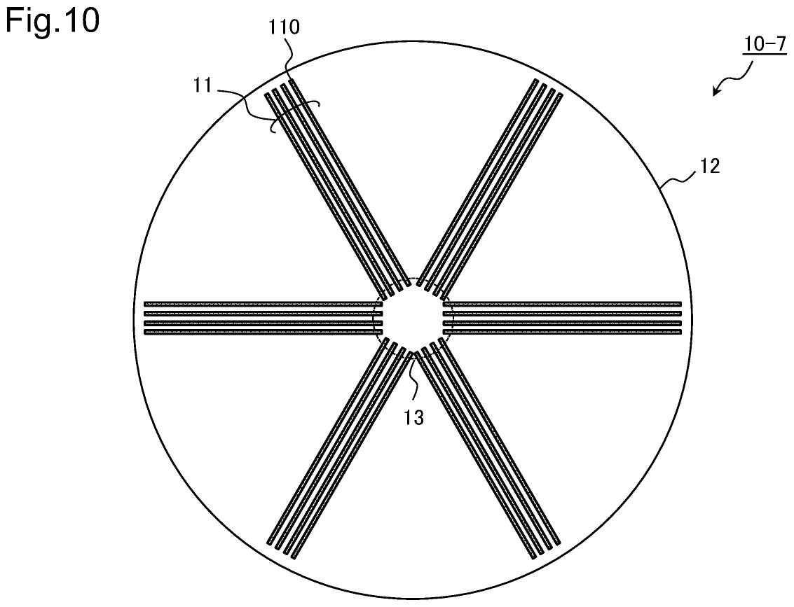

FIG. 10 is a plan view illustrating an example of a configuration of a light-receiving device 10-7 of a seventh modification example. The substrate 12 has a circular shape in plan view. The light-receiving device 10-7 includes one light-receiving element 13. The light-receiving element 13 is disposed at a position indicated by a dotted circle including the center of the circular substrate 12.

The light-receiving device 10-7 includes a plurality of optical antennas 11 including a plurality of waveguide pipes 110 radially extending in the radial direction from the vicinity of the center of the circular substrate 12. Emission ends of the plurality of waveguide pipes 110 constituting each of the plurality of optical antennas 11 are disposed to face the light-receiving surface of the light-receiving element 13. The end portions of the plurality of waveguide pipes 110 constituting the optical antenna 11 on the side opposite to the emission ends are disposed in the radial direction of the circular substrate 12. The light-receiving surface of the light-receiving element 13 is disposed so as to face the emission ends of the plurality of waveguide pipes 110 constituting the optical antenna 11 with the substrate 12 interposed therebetween.

According to the present modification example, the light received by the optical antenna 11 including the plurality of waveguide pipes 110 radially formed on the first surface of the circular substrate 12 can be guided to the light-receiving surface of the single light-receiving element 13.

### Eighth Modification Example

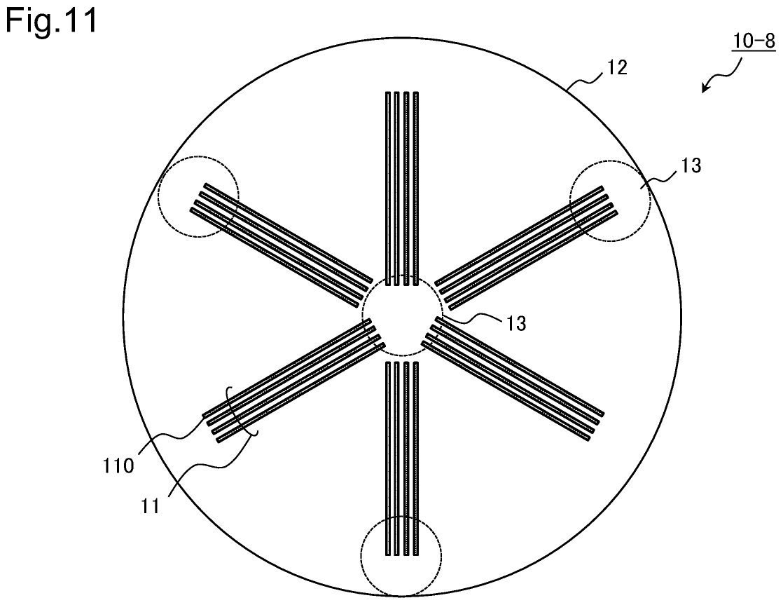

FIG. 11 is a plan view illustrating an example of a configuration of a light-receiving device 10-8 of an eighth modification example. The substrate 12 has a circular shape in plan view. The light-receiving device 10-8 includes a plurality of light-receiving elements 13. The plurality of light-receiving elements 13 are disposed at positions indicated by a dotted circle including the center of the circular substrate 12 or a dotted circle near the circumference.

The light-receiving device 10-8 includes a plurality of optical antennas 11 including a plurality of waveguide pipes 110 radially extending in the radial direction from the vicinity of the center of the circular substrate 12. Emission ends of the plurality of waveguide pipes 110 constituting each of the plurality of optical antennas 11 are disposed to face any light-receiving surface of the plurality of light-receiving elements 13. The end portion of the optical antenna 11 on the side opposite to the emission ends of the plurality of waveguide pipes 110 is disposed toward the circumference or the center of the circular substrate 12. The light-receiving surface of the light-receiving element 13 is disposed so as to face the emission ends of the plurality of waveguide pipes 110 constituting the optical antenna 11 with the substrate 12 interposed therebetween.

According to the present modification example, the light received by the optical antenna 11 including the plurality of waveguide pipes 110 radially formed on the first surface of the circular substrate 12 can be guided to the light-receiving surfaces of the plurality of light-receiving elements 13.

As described above, the light-receiving device of the present example embodiment includes the optical antenna, the substrate, and the light-receiving element. The optical antenna is formed on the first surface of the substrate. The optical antenna receives a spatial light signal. The optical antenna guides signal light derived from the spatial light signal to an emission end along an in-plane direction of the substrate. The optical antenna emits signal light from the emission end toward the substrate. The substrate transmits light in the wavelength band of the spatial light signal to be received. The light-receiving element is disposed with the light-receiving surface facing the second surface facing the first surface of the substrate. The light-receiving element receives signal light emitted from the optical antenna on a light-receiving surface.

For example, the optical antenna includes a plurality of waveguide pipes including a light-receiving portion that receives a spatial light signal, a light guide path through which signal light derived from the spatial light signal is guided, and an emission end from which signal light guided through the light guide path is emitted. The emission ends of the plurality of waveguide pipes are disposed toward the light-receiving surface of the light-receiving element with the substrate interposed therebetween. For example, the optical antenna is a waveguide grating antenna.

The light-receiving device according to the present example embodiment efficiently guides signal light derived from a spatial light signal to a light-receiving element including a light-receiving portion having a small opening area capable of obtaining high-speed responsiveness. Therefore, according to the light-receiving device of the present example embodiment, the spatial light signal can be efficiently received.

A light-receiving device according to one aspect of the present example embodiment includes a plurality of optical antennas in which emission ends are disposed on a first surface of a substrate toward a light-receiving surface of a light-receiving element with the substrate interposed therebetween. In the light-receiving device of the present aspect, the light-receiving area of the spatial light signal can be increased by configuring the light-receiving device with the plurality of optical antennas. Therefore, according to the light-receiving device of the present aspect, the spatial light signal can be more efficiently received.

### Second Example Embodiment

Next, a light-receiving device according to a second example embodiment will be described with reference to the drawings. The light-receiving device of the present example embodiment is different from the light-receiving device of the first example embodiment in that a trench is formed at a position where the light-receiving element is disposed on the second surface of the substrate.

(Configuration)

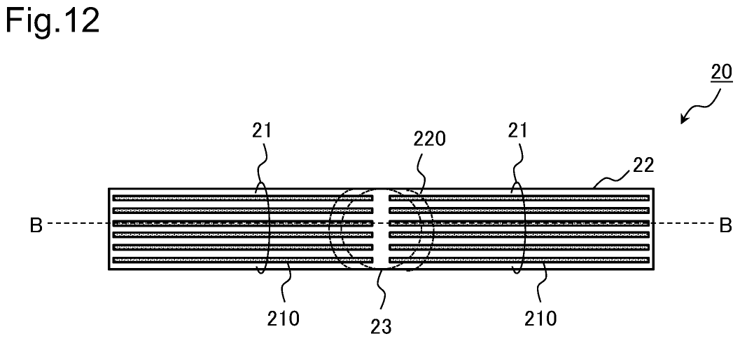

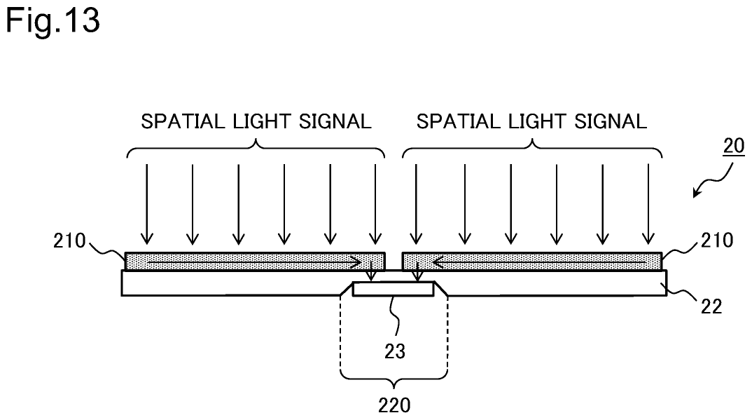

FIG. 12 is a plan view illustrating an example of a configuration of a light-receiving device 20 of the present example embodiment. FIG. 13 is a cross-sectional view of the light-receiving device 20 taken along line B-B in FIG. 12. FIG. 13 conceptually illustrates a trajectory of a spatial light signal incident on the light-receiving device 20 and light traveling inside the light-receiving device 20 by an arrow. The light-receiving device 20 includes an optical antenna 21, a substrate 22, and a light-receiving element 23. FIGS. 12 to 13 illustrate the light-receiving device 20 including two sets of optical antennas 21. In FIG. 12, the position of a trench 220 formed in the substrate 22 and the position of the light-receiving element 23 disposed in the portion of the trench 220 on the back surface (second surface) side of the substrate 22 are indicated by dotted lines.

The optical antenna 21 is formed on the first surface of the substrate 22. The optical antenna 21 includes a plurality of waveguide pipes 210. Since the optical antenna 21 has the same configuration as the optical antenna 11 of the first example embodiment, detailed description thereof will be omitted.

The substrate 22 has a rectangular shape in plan view. The waveguide pipe 210 is disposed on the first surface of the substrate 22. The trench 220 is formed near the center of the second surface facing the first surface of the substrate 22. For example, the trench 220 can be formed by excavating the second surface of the substrate 22. The light-receiving element 23 is disposed in a portion of the trench 220 on the second surface facing the first surface of the substrate 22. The material of the substrate 22 is similar to that of the substrate 12 of the first example embodiment.

The light-receiving element 23 is disposed in a portion of the trench 220 formed on the second surface side of the substrate 22. The light-receiving element 23 has a light-receiving surface that receives light in the wavelength band of the spatial light signal. The light-receiving element 23 is disposed such that the light-receiving surface thereof faces an emission end of the waveguide pipe 210 via a portion of the trench 220 of the substrate 22. The light emitted from the emission end of the waveguide pipe 210 passes through the portion of the trench 220 of the substrate 22 and is received by the light-receiving surface of the light-receiving element 23. The light-receiving element 23 has the same configuration as the light-receiving element 13 of the first example embodiment.

As described above, the light-receiving device of the present example embodiment includes the optical antenna, the substrate, and the light-receiving element. The optical antenna is formed on the first surface of the substrate. The optical antenna receives a spatial light signal. The optical antenna guides signal light derived from the spatial light signal to an emission end along an in-plane direction of the substrate. The optical antenna emits signal light from the emission end toward the substrate. The substrate transmits light in the wavelength band of the spatial light signal to be received. A trench is formed on the second surface of the substrate. The light-receiving element is disposed at the position of the trench with the light-receiving surface facing the second surface facing the first surface of the substrate. The light-receiving element receives signal light emitted from the optical antenna on a light-receiving surface.

In the light-receiving device of the present example embodiment, since the trench is formed in the substrate, the thickness of the substrate through which the light emitted from the emission end of the optical antenna passes is reduced, so that the attenuation amount of the light when passing through the substrate is reduced. Therefore, according to the light-receiving device of the present example embodiment, the light-receiving efficiency of the light-receiving element can be improved as compared with the first example embodiment.

### Third Example Embodiment

Next, a light-receiving device according to a third example embodiment will be described with reference to the drawings. A light-receiving device of the present example embodiment is different from the light-receiving device of the first example embodiment in that a reflecting mirror is disposed at an end portion (also referred to as an opposite end portion) on an opposite side to emission ends of a plurality of waveguide pipes constituting an optical antenna. The light-receiving device of the present example embodiment may be combined with the light-receiving device of the second example embodiment.

(Configuration)

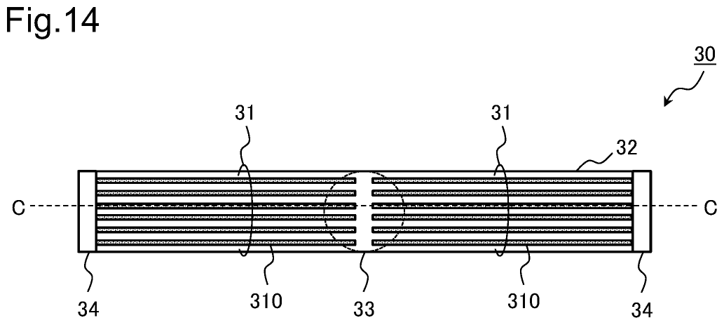

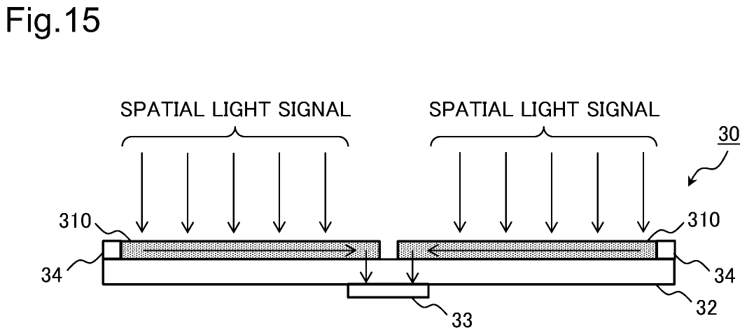

FIG. 14 is a plan view illustrating an example of a configuration of a light-receiving device 30 of the present example embodiment. FIG. 15 is a cross-sectional view of the light-receiving device 30 taken along line C-C in FIG. 14. FIG. 15 conceptually illustrates a trajectory of a spatial light signal incident on the light-receiving device 30 and light traveling inside the light-receiving device 30 by an arrow. The light-receiving device 30 includes an optical antenna 31, a substrate 32, a light-receiving element 33, and a reflecting mirror 34. FIGS. 14 and 15 illustrate the light-receiving device 30 including two sets of optical antennas 31. In FIG. 14, the position of the light-receiving element 33 disposed at the position of the back surface (second surface) of the substrate 32 is indicated by a dotted line.

The optical antenna 31 is formed on the first surface of the substrate 32. The optical antenna 31 includes a plurality of waveguide pipes 310. Since the optical antenna 31 has the same configuration as the optical antenna 11 of the first example embodiment, detailed description thereof will be omitted.

The substrate 32 has a rectangular shape in plan view. The waveguide pipe 310 is disposed on the first surface of the substrate 32. The light-receiving element 33 is disposed on the second surface facing the first surface of the substrate 32. The material of the substrate 32 is similar to that of the substrate 12 of the first example embodiment.

The light-receiving element 33 is disposed on the second surface of the substrate 32. The light-receiving element 33 is disposed near the center of the substrate 32. The light-receiving element 33 has a light-receiving surface that receives light in the wavelength band of the spatial light signal. The light-receiving element 33 is disposed such that the light-receiving surface thereof faces an emission end of the waveguide pipe 310 via the substrate 32. The light emitted from the emission end of the waveguide pipe 310 is transmitted through the substrate 32 and received by the light-receiving surface of the light-receiving element 33. The light-receiving element 33 has the same configuration as the light-receiving element 13 of the first example embodiment.

The reflecting mirror 34 is disposed on the first surface of the substrate 32. The reflecting mirror 34 has a reflecting surface that reflects light in the wavelength band of the spatial light signal. The reflecting mirror 34 is disposed near both left and right ends of the substrate 32. The reflecting mirror 34 is disposed such that the reflecting surface is perpendicular to the central axes of the plurality of waveguide pipes 310 constituting the optical antenna 31. The opposite end portion of the waveguide pipe 310 faces the reflecting surface of the reflecting mirror 34. The light reaching the reflecting surface of the reflecting mirror 34 from the opposite end portion of the waveguide pipe 310 is reflected by the reflecting surface and travels through the light guide path inside the waveguide pipe 310 toward the emission end.

As described above, the light-receiving device of the present example embodiment includes the optical antenna, the reflecting mirror, the substrate, and the light-receiving element. The optical antenna is formed on the first surface of the substrate. The optical antenna receives a spatial light signal. The optical antenna guides signal light derived from the spatial light signal to an emission end along an in-plane direction of the substrate. The optical antenna emits signal light from the emission end toward the substrate. The reflecting mirror is disposed at an end portion of the optical antenna opposite to the emission end, and reflects the signal light toward the emission end. The substrate transmits light in the wavelength band of the spatial light signal to be received. The light-receiving element is disposed with the light-receiving surface facing the second surface facing the first surface of the substrate. The light-receiving element receives signal light emitted from the optical antenna on a light-receiving surface.

According to the light-receiving device of the present example embodiment, the signal light is reflected toward the emission end by the reflecting mirror disposed at the end portion on the opposite side to the emission end of the optical antenna, so that the light-receiving efficiency of the light-receiving element can be improved as compared with the first example embodiment.

### Fourth Example Embodiment

Next, a light-receiving device according to a fourth example embodiment will be described with reference to the drawings. A light-receiving device of the present example embodiment is different from the light-receiving device of the first example embodiment in that a light pipe that guides light toward a light-receiving surface of a light-receiving element is disposed between a second surface of a substrate and the light-receiving surface of the light-receiving element. The light-receiving device of the present example embodiment may be combined with the light-receiving devices of the second and third example embodiments.

(Configuration)

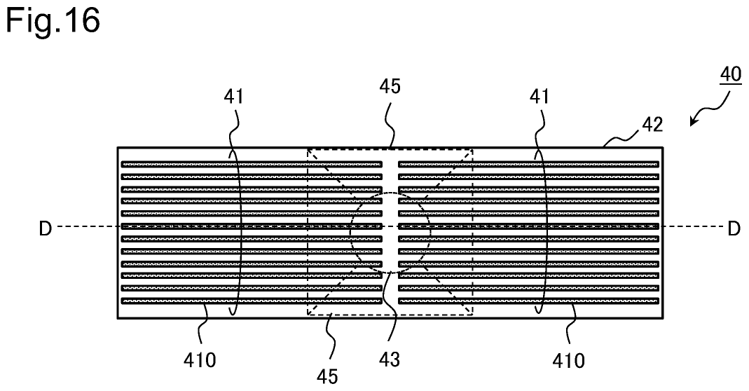

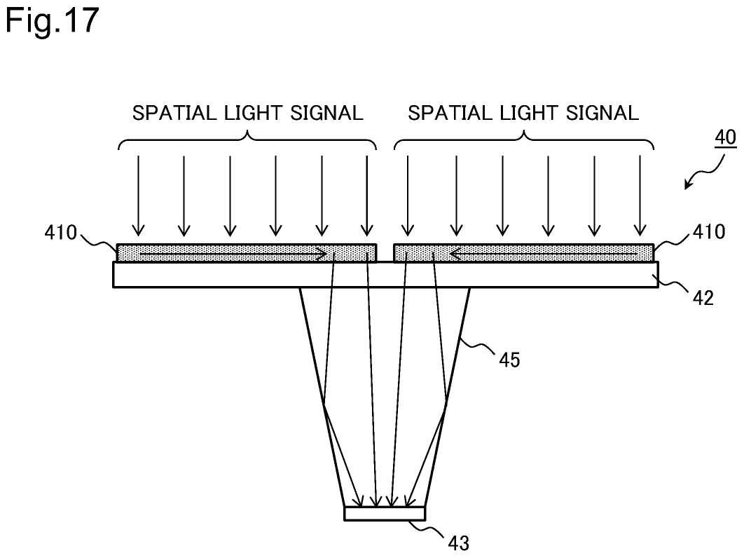

FIG. 16 is a plan view illustrating an example of a configuration of a light-receiving device 40 of the present example embodiment. FIG. 17 is a cross-sectional view of the light-receiving device 40 taken along line D-D in FIG. 16. FIG. 17 conceptually illustrates a trajectory of a spatial light signal incident on the light-receiving device 40 and light traveling inside the light-receiving device 40 by an arrow. The light-receiving device 40 includes an optical antenna 41, a substrate 42, a light-receiving element 43, and a light pipe 45. FIGS. 16 and 17 illustrate the light-receiving device 40 including two sets of optical antennas 41. In FIG. 17, the positions of the light-receiving element 43 and the light pipe 45 disposed on the back surface (second surface) of the substrate 42 are indicated by dotted lines.

The optical antenna 41 is formed on the first surface of the substrate 42. The optical antenna 41 includes a plurality of waveguide pipes 410. The emission ends of the plurality of waveguide pipes 410 are disposed to face the incident surface of the light pipe 45 disposed on the second surface via the substrate 42. Since the optical antenna 41 has the same configuration as the optical antenna 11 of the first example embodiment, detailed description thereof will be omitted. The number of the plurality of waveguide pipes 410 constituting the optical antenna 41 may be associated with the incident surface of the light pipe 45 larger than the area of the light-receiving surface of the light-receiving element 43. Therefore, the optical antenna 41 of the present example embodiment can increase the number of waveguide pipes 410 as compared with the optical antenna 11 of the first example embodiment.

The substrate 42 has a rectangular shape in plan view. The waveguide pipe 410 is disposed on the first surface of the substrate 42. The light pipe 45 is disposed near the center of the second surface facing the first surface of the substrate 42. The material of the substrate 42 is similar to that of the substrate 12 of the first example embodiment.

The light pipe 45 is disposed in association with the light-receiving element 43. The light pipe 45 has an incident surface facing the substrate 42 and an emission surface facing the light-receiving surface of the light-receiving element 43. The emission surface has a smaller area than the incident surface. The incident surface of the light pipe 45 is disposed so as to be in contact with the substrate 42. The light emitted from the emission ends of the plurality of waveguide pipes 410 is incident on the incident surface of the light pipe 45. As long as the light emitted from the emission ends of the plurality of waveguide pipes 410 is incident on the incident surface of the light pipe 45, the incident surface of the light pipe 45 and the substrate 42 may not be in contact with each other. Although FIG. 17 illustrates an example in which the incident surface and the emission surface of the light pipe 45 are parallel to each other, the incident surface and the emission surface may be non-parallel as long as light can be guided from the incident surface toward the emission surface.

The light pipe 45 may be made of a material that easily transmits light in a wavelength band of spatial light. For example, the light pipe 45 can be made of a material of a general optical fiber. On the outer surface of the light pipe 45, a reflecting surface that reflects light in a wavelength band of signal light toward the inside of the light pipe 45 is formed. The signal light incident from the incident surface of the light pipe 45 is guided to the emission surface while being reflected by the side surface of the light pipe 45. The signal light guided to the emission surface is emitted from the emission surface. Most of the signal light guided inside the light pipe may be emitted from the emission surface, and a part of the signal light may leak from the side surface.

The interior of the light pipe 45 may be hollow. The inner surface of the light pipe 45 reflects light in a wavelength band of signal light. For example, a reflector that reflects light in a wavelength band of signal light may be installed on the inner surface of the light pipe 45. The main body of the light pipe 45 may be made of a material that transmits light in a wavelength band of signal light, and a reflector that reflects the signal light may be installed on a side surface of the light pipe 45. The light reflected inside the light pipe 45 is emitted from the emission surface and received by the light-receiving surface of the light-receiving element 43. When the light pipe 45 is hollow, the signal light is not attenuated inside the light pipe, so that the intensity of light reaching the light-receiving surface of the light-receiving element 43 increases as compared with the case where the inside is not hollow.

The light-receiving element 43 has a light-receiving surface that receives light in the wavelength band of the spatial light signal. The light-receiving element 43 is disposed with its light-receiving surface facing the emission surface of the light pipe 45. The light-receiving element 43 is disposed such that a light-receiving surface thereof faces an emission end of the waveguide pipe 410 via the light pipe 45. The light emitted from the emission end of the waveguide pipe 410 is received by the light-receiving surface of the light-receiving element 43 via the light pipe 45. The light-receiving element 43 has the same configuration as the light-receiving element 13 of the first example embodiment.

As described above, the light-receiving device of the present example embodiment includes the optical antenna, the substrate, the light pipe, and the light-receiving element. The optical antenna is formed on the first surface of the substrate. The optical antenna receives a spatial light signal. The optical antenna guides signal light derived from the spatial light signal to an emission end along an in-plane direction of the substrate. The optical antenna emits signal light from the emission end toward the substrate. The substrate transmits light in the wavelength band of the spatial light signal to be received. The light pipe is disposed between the second surface of the substrate and the light-receiving surface of the light-receiving element. The light pipe guides the signal light emitted from the emission end of the optical antenna to the light-receiving surface of the light-receiving element. The light-receiving element is disposed with the light-receiving surface facing the emission surface of the light pipe. The light-receiving element receives signal light emitted from the optical antenna on a light-receiving surface.

The light-receiving device of the present example embodiment guides light emitted from the emission ends of the plurality of waveguide pipes constituting the optical antenna to the light-receiving surface of the light-receiving element by the light pipe. Therefore, according to the light-receiving device of the present example embodiment, it is possible to cause the light-receiving element including the light-receiving portion having a small opening area exhibiting high-speed responsiveness to receive the signal light. According to the light-receiving device of the present example embodiment, a larger amount of light can be guided to the light-receiving surface of the light-receiving element as compared with the first example embodiment. In the light-receiving device of the present example embodiment, the number of the plurality of waveguide pipes constituting the optical antenna can be set in association with the incident surface of the light pipe having an area larger than the light-receiving surface of the light-receiving element. Therefore, according to the light-receiving device of the present example embodiment, since the number of waveguide pipes associated with one light-receiving element can be increased as compared with the first example embodiment, the spatial light signal can be more efficiently received.

### Fifth Example Embodiment

Next, a light-receiving device according to a fifth example embodiment will be described with reference to the drawings. A light-receiving device of the present example embodiment is different from the light-receiving device of the first example embodiment in that phase shifters that align phases of light having passed through a plurality of waveguide pipes constituting an optical antenna are disposed. The light-receiving device of the present example embodiment may be combined with the light-receiving devices of the second to fourth example embodiments.

(Configuration)

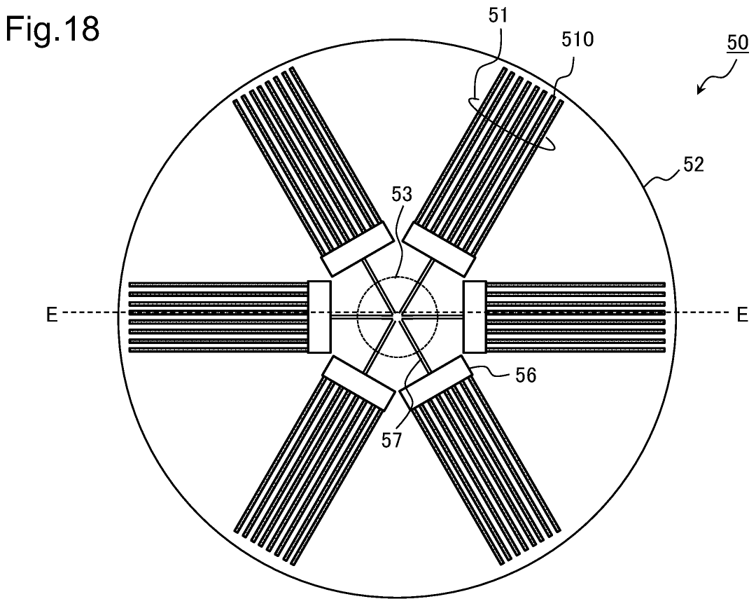

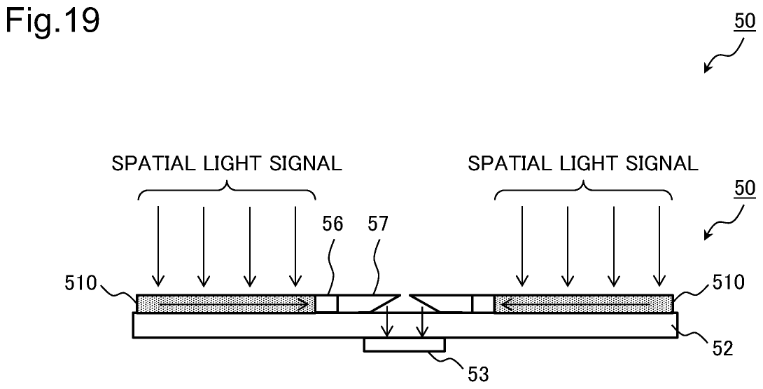

FIG. 18 is a plan view illustrating an example of a configuration of a light-receiving device 50 of the present example embodiment. FIG. 19 is a cross-sectional view of the light-receiving device 50 taken along line E-E in FIG. 18. FIG. 19 conceptually illustrates a trajectory of a spatial light signal incident on the light-receiving device 50 and light traveling inside the light-receiving device 50 by an arrow. The light-receiving device 50 includes an optical antenna 51, a substrate 52, a light-receiving element 53, a phase shifter 56, and a waveguide 57. The optical antenna 51, the phase shifter 56, and the waveguide 57 constitute a light-receiving unit. The light-receiving device 50 in FIG. 18 includes six sets of light-receiving units. In FIG. 18, the position of the light-receiving element 53 disposed at the position of the back surface (second surface) of the substrate 52 is indicated by a dotted line.

The optical antenna 51 is formed on the first surface of the substrate 52. The optical antenna 51 includes a plurality of waveguide pipes 510. Lengths of the plurality of waveguide pipes 510 constituting the same light-receiving unit are the same. The plurality of waveguide pipes 510 are disposed radially along the radial direction with the emission end facing the center of the circular substrate 52. Emission ends of the plurality of waveguide pipes 510 are connected to an input end of the phase shifter 56. The light emitted from the emission ends of the plurality of waveguide pipes 510 is input to the phase shifter 56. The optical antenna 51 has the same configuration as the optical antenna 11 of the first example embodiment.

The substrate 52 has a circular shape in plan view. Six sets of light-receiving units including the optical antenna 51, the phase shifter 56, and the waveguide 57 are disposed on the first surface of the substrate 52. The light-receiving element 53 is disposed on the second surface facing the first surface of the substrate 52. The material of the substrate 52 is similar to that of the substrate 12 of the first example embodiment.

The light-receiving element 53 is disposed on the second surface of the substrate 52. The light-receiving element 53 is disposed at the center of the circular substrate 52. The light-receiving element 53 has a light-receiving surface that receives light in the wavelength band of the spatial light signal. The light-receiving element 53 is disposed such that a light-receiving surface thereof faces an emission end of the waveguide 57 via the substrate 52. The light emitted from the emission end of the waveguide 57 is transmitted through the substrate 52 and received by the light-receiving surface of the light-receiving element 53. The light-receiving element 53 has the same configuration as the light-receiving element 13 of the first example embodiment.

The phase shifter 56 is disposed on the first surface of the substrate 52 in association with each of the plurality of optical antennas 51. Emission ends of the plurality of waveguide pipes 510 are connected to an input end of the phase shifter 56. An input end of the waveguide 57 is connected to an output end of the phase shifter. The phase shifter 56 adjusts the phase of the signal light so that the phases of the signal light received by the plurality of waveguide pipes 510 constituting the optical antenna 51 are the same in the light-receiving portion of the light-receiving element 53. That is, the phase shifter 56 corrects the phase shift of the spatial light signal received by the optical antenna, and adjusts the phase of the signal light such that the phase of the signal light derived from the spatial light signal is aligned at the position of the light-receiving portion of the light-receiving element 53.

For example, the phase shifter 56 is realized by an active phase shifter that adjusts the phase of the signal light under the control of a control unit (not illustrated). When the active phase shifter is used, it is possible to align the phases when the signal light is input to the light-receiving portion of the light-receiving element 53 and to correct the phase shift of the spatial light signal received by the optical antenna 51. When the active phase shifter is used, the phase of the signal light derived from the spatial light signal received by the optical antenna 51 is aligned at the timing when the signal light is received by the light-receiving portion of the light-receiving element 53, so that the spatial light signal arriving from an arbitrary direction can be received. When the arrival direction of the spatial light signal is limited to a certain direction, for example, the phase shifter 56 can be realized by a passive phase shifter in which a phase shift amount is set in advance. The light having passed through the passive phase shifter 56 is shifted in phase by a shift amount set in advance. For example, the phase shifter 56 adjusts the phase of the signal light by changing the refractive index of the input light. For example, the phase shifter 56 is realized by a thermo-optical type phase shifter utilizing a thermo-optical effect or a carrier injection type phase shifter utilizing a carrier injection effect.

In the present example embodiment, the phase shift amount is adjusted for each of the plurality of phase shifters 56 such that the phases of the light incident on the optical antennas 51 of the six sets of light-receiving units become the same when the light is received by the light-receiving surface of the light-receiving element 53. For example, the phase shift amount of the phase shifter 56 is adjusted according to the arrival direction of the spatial light signal to be received, the lengths of the plurality of waveguide pipes 510, and the length of the waveguide 57.

The waveguide 57 is formed on the first surface of the substrate 52 in association with each of the plurality of phase shifters 56. The lengths of the waveguides 57 included in the light-receiving device 50 are all the same. An output end of the phase shifter 56 is connected to an input end of the waveguide 57. The emission end of the waveguide 57 is disposed toward the light-receiving surface of the light-receiving element 53 with the substrate 52 interposed therebetween. In the example of FIG. 19, the emission end of the waveguide 57 has a shape obliquely cut toward the light-receiving surface of the light-receiving element 53. The shape of the emission end of the waveguide 57 is not limited as long as the emission end can output light toward the light-receiving surface of the light-receiving element 53. The light incident from the input end of the waveguide 57 travels inside the waveguide 57 and is emitted from the emission end. The material of the waveguide 57 is not particularly limited as long as the transmittance of light in the wavelength band of the spatial light signal is high. For example, the waveguide 57 is formed on the first surface of the substrate 52 using a silicon photonics technology.

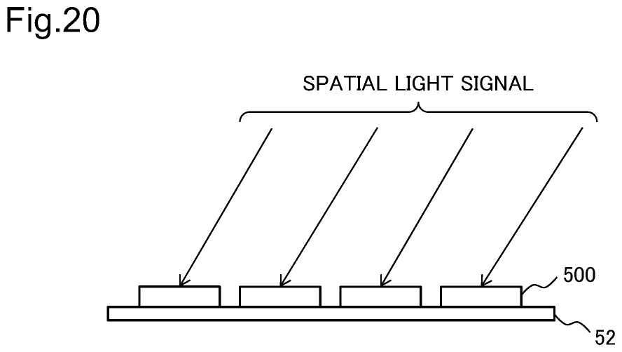

FIG. 20 is a conceptual diagram illustrating an example of a trajectory of a spatial light signal of a light-receiving target in a case where an arrival direction of the spatial light signal is one direction. When the arrival direction of the spatial light signal is one direction, the phase shifter 56 can be realized by an active or passive phase shifter. FIG. 20 illustrates a state in which a plurality of light-receiving units 500 each including the optical antenna 51, the phase shifter 56, and the waveguide 57 are disposed on the first surface of the substrate 52. The phase shift amount by the phase shifter 56 included in each of the plurality of light-receiving units 500 is adjusted such that the phases of the light derived from the spatial light signal arriving from one direction are the same on the light-receiving surface of the light-receiving element 53. In the example of FIG. 18, the direction of the waveguide pipe 510 of the optical antenna 51 with respect to the arrival direction of the spatial light signal is different for each light-receiving unit 500. Therefore, the phase shift amount of the phase shifter 56 included in each of the plurality of light-receiving units 500 is adjusted such that the phases of the light derived from the spatial light signal arriving from one direction are the same on the light-receiving surface of the light-receiving element 53.

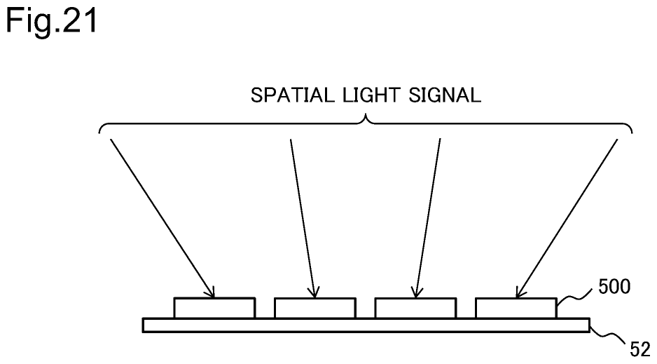

FIG. 21 is a conceptual diagram illustrating an example of a trajectory of a spatial light signal in a case where arrival directions of spatial light signals to be received are various. In a case where the arrival directions of the spatial light signals are various, the phase shifter 56 can be realized by an active phase shifter. FIG. 21 illustrates a state in which a plurality of light-receiving units 500 each including the optical antenna 51, the phase shifter 56, and the waveguide 57 are disposed on the first surface of the substrate 52. The phase shift amount by the phase shifter 56 included in each of the plurality of light-receiving units 500 is adjusted such that the phases of the light derived from the spatial light signals arriving from various directions are the same on the light-receiving surface of the light-receiving element 53. In the example of FIG. 18, the direction of the waveguide pipe 510 of the optical antenna 51 with respect to the arrival direction of the spatial light signal is different for each light-receiving unit 500. Therefore, the phase shift amount of the phase shifter 56 included in each of the plurality of light-receiving units 500 is adjusted such that the phases of the light derived from the spatial light signals arriving from various directions are the same on the light-receiving surface of the light-receiving element 53.

### Ninth Modification Example

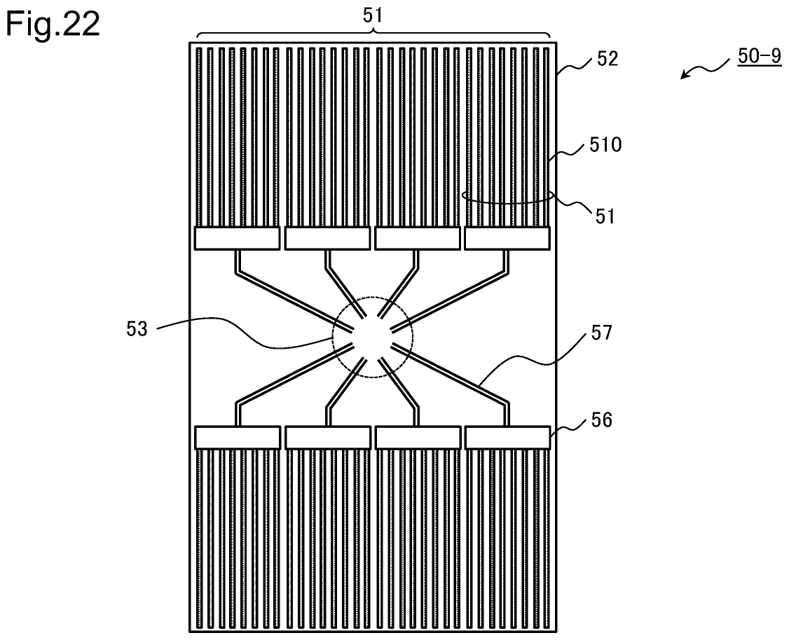

FIG. 22 is a plan view illustrating an example of a configuration of a light-receiving device 50-9 of a ninth modification example of the light-receiving device 50 of the present example embodiment. The substrate 52 has a rectangular shape in plan view. The light-receiving device 50-9 includes one light-receiving element 53. The light-receiving element 53 is disposed at a position indicated by a dotted circle at the center of the second surface of the substrate 52.

The optical antenna 51 is formed on the first surface of the substrate 52. The plurality of waveguide pipes 510 constituting the optical antenna 51 extend from two opposing long sides of the rectangular substrate 52 in a direction perpendicular to the long sides. In the example of FIG. 22, the upper waveguide pipe 510 extends downward, and the lower waveguide pipe 510 extends upward. Emission ends of the plurality of waveguide pipes 510 are connected to an input end of the phase shifter 56. An output end of the phase shifter 56 is connected to an input end of the waveguide 57. The emission end of the waveguide 57 is disposed toward the light-receiving surface of the light-receiving element 53 with the substrate 52 interposed therebetween. The length of the waveguide 57 included in the light-receiving device 50-9 varies depending on the position of the light-receiving unit. The waveguide 57 of the light-receiving unit farther from the light-receiving element 53 is longer than the waveguide 57 of the light-receiving unit closer to the light-receiving element 53. Therefore, the phase shifter 56 is adjusted to shift the phase of the light by a shift amount corresponding to the position of the light-receiving unit.

In the case of the present modification example, when the arrival direction of the spatial light signal is one direction, the directions of the plurality of waveguide pipes 510 with respect to the arrival direction of the spatial light signal are the same. Therefore, it is not necessary to shift the phase of the light in accordance with the arrival direction of the spatial light signal. However, since the positions of the phase shifter 56 and the light-receiving element 53 are different according to the position of the light-receiving portion on the substrate 52, the length of the waveguide 57 is different for each light-receiving portion. Therefore, the phase shift amount of the phase shifter 56 of the light-receiving device 50-9 is adjusted according to the position of the light-receiving portion on the substrate 52. In a case where the arrival direction of the spatial light signal is various, a light-receiving portion may be allocated for each arrival direction of the spatial light signal, and the phase shift amount of the phase shifter 56 may be adjusted according to the arrival direction of the spatial light signal and the position of the light-receiving portion on the substrate 52.

As described above, the light-receiving device of the present example embodiment includes the optical antenna, the phase shifter, the waveguide pipe, the substrate, and the light-receiving element. The optical antenna is formed on the first surface of the substrate. The optical antenna receives a spatial light signal. The optical antenna guides signal light derived from the spatial light signal to an emission end along an in-plane direction of the substrate. The optical antenna emits signal light from the emission end toward the substrate. The phase shifter is connected to an emission end of the optical antenna. The phase shifter adjusts the phase of the input signal light and outputs the signal light from the output end such that the phase of the signal light is aligned at the position of the light-receiving portion of the light-receiving element. The waveguide is connected to an output end of the phase shifter. The signal light output from the phase shifter is input to the waveguide. The waveguide emits the input signal light toward the light-receiving surface of the light-receiving element. The substrate transmits light in the wavelength band of the spatial light signal to be received. The light-receiving element is disposed with the light-receiving surface facing the second surface facing the first surface of the substrate. The light-receiving element receives signal light emitted from the optical antenna on a light-receiving surface.

According to the present example embodiment, the phases of the light received by the plurality of optical antennas can be aligned using the phase shifter. Therefore, according to the present example embodiment, by providing directivity in accordance with the arrival direction of the spatial light signal, it is possible to receive the spatial light signal arriving from an arbitrary direction. According to the present example embodiment, since the phase can be adjusted by the phase shifter, the waveguide pipe can have a different length for each optical antenna. Therefore, according to the present example embodiment, since the length of the optical antenna can be varied, the density of the optical antenna can be increased by devising the arrangement of the optical antenna. For example, when an active phase shifter is used, it is also possible to cancel noise light deviated from a phase of a spatial light signal to be received by using light having a phase opposite to that of the noise light.

### Sixth Example Embodiment

Next, a light-receiving device according to a sixth example embodiment will be described with reference to the drawings. A light-receiving device of the present example embodiment is different from the light-receiving device of the first example embodiment in that the light-receiving device receives a spatial light signal arriving from an arbitrary direction in a predetermined plane. The light-receiving device of the present example embodiment may be combined with the light-receiving devices of the second to fifth example embodiments.

(Configuration)

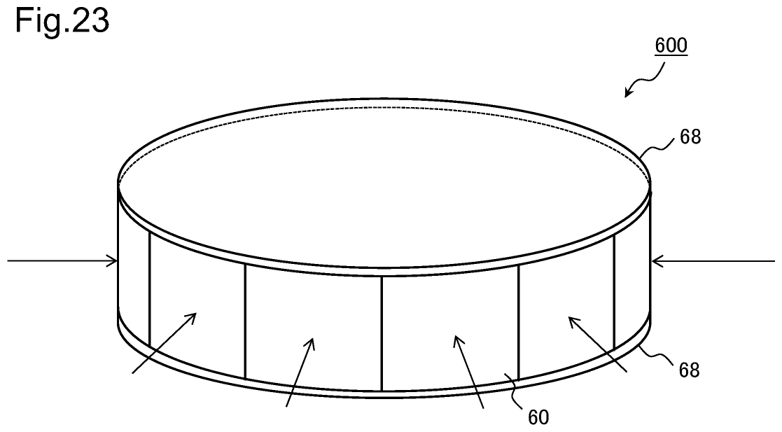

FIG. 23 is a conceptual diagram illustrating an example of a configuration of a light-receiving device 600 of the present example embodiment. FIG. 23 is a diagram of the light-receiving device 600 as viewed from an obliquely upper viewing seat. The light-receiving device 600 includes a plurality of light receivers 60. The plurality of light receivers 60 are disposed on the side surface of the cylindrical light-receiving device 600 with the light-receiving surface facing outward. That is, the plurality of optical antennas constituting each of the plurality of light receivers 60 is disposed along the circumference of a specific circle with the light-receiving surface facing the radial direction of the specific circle. Support bodies 68 for supporting the plurality of light receivers 60 are disposed in an upper portion and a lower portion of the light-receiving device 600. In order to prevent disturbance by light transmitted through the support body 68, the support body 68 may do not transmit light in a wavelength band of a spatial light signal to be received. The support body 68 is not limited to a shape or a material as long as it can support the plurality of light receivers 60. Each of the plurality of light receivers 60 has at least one configuration of the light-receiving devices of the first to fifth example embodiments. All of the plurality of light receivers 60 may have the same configuration, or different configurations may be combined. The detailed configuration of each of the plurality of light receivers 60 will not be described.

The light-receiving device 600 includes a light-receiving element that receives light derived from a spatial light signal. The light-receiving element may be provided for each of the plurality of light receivers 60, or may be provided in common for the plurality of light receivers 60. In a case where a common light-receiving element is provided for the plurality of light receivers 60, a light guide that guides light received by the light receivers 60 to a light-receiving surface of the light-receiving element may be provided. The light-receiving device 600 receives a spatial light signal arriving from all directions on the side by any one of the light receivers 60. For example, when the size of the light-receiving surface of the light receiver 60 is on the order of centimeters, the light-receiving device 600 can receive a spatial light signal transmitted from a position about several tens to hundreds of meters away. An arrival direction of the spatial light signal received by each of the plurality of light receivers 60 is limited to one direction. Therefore, not only an active phase shifter but also a passive phase shifter can be used as the plurality of light receivers 60. When the light-receiving device 600 is inclined, the light-receiving direction of the light-receiving device 600 can be changed by orienting the light-receiving surfaces of the plurality of light receivers 60 in a desired direction. For example, if the inclination of the light-receiving device 600 can be mechanically controlled, the light-receiving surfaces of the plurality of light receivers 60 can be directed in a desired direction.

As described above, the light-receiving device of the present example embodiment includes the plurality of optical antennas, the substrate, and the light-receiving element. The plurality of optical antennas are formed on the first surface of the substrate. The plurality of optical antennas are disposed along a circumference of a specific circle with a light-receiving surface facing a radial direction of the specific circle. The plurality of optical antennas receive spatial light signals. The plurality of optical antennas guide the signal light derived from the spatial light signal to the emission end along the in-plane direction of the substrate. The plurality of optical antennas emit signal light from the emission end toward the substrate. The substrate transmits light in the wavelength band of the spatial light signal to be received. The light-receiving element is disposed with the light-receiving surface facing the second surface facing the first surface of the substrate. The light-receiving element receives signal light emitted from the plurality of optical antennas on the light-receiving surface.

According to the light-receiving device of the present example embodiment, the spatial light signal arriving from all directions in the predetermined plane can be received by the plurality of optical antennas without using the lens system such as the condensing lens. Since the light-receiving device of the present example embodiment does not include a lens system such as a condensing lens, the size can be reduced as compared with a device including a lens system.

### Seventh Example Embodiment

Next, a receiving device according to a seventh example embodiment will be described with reference to the drawings. The receiving device of the present example embodiment includes at least one of the light-receiving devices of the first to sixth example embodiments. The receiving device of the present example embodiment includes a decoder that decodes the spatial light signal received by the light-receiving device.

(Configuration)

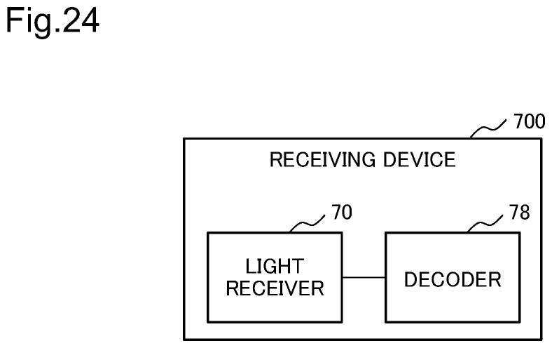

FIG. 24 is a conceptual diagram illustrating an example of a configuration of a receiving device 700 according to the present example embodiment. The receiving device 700 includes a light receiver 70 and a decoder 78. FIG. 24 is a view illustrating an internal configuration of the receiving device 700 when the internal configuration is viewed from the lateral direction. The position of the decoder 78 is not particularly limited. The decoder 78 may be disposed inside the receiving device 700 or may be disposed outside the receiving device 700.

The light receiver 70 is any one of the light-receiving devices of the first to sixth example embodiments. Some of the light-receiving devices of the first to sixth example embodiments may be combined to configure the light receiver 70. The light receiver 70 converts light (also referred to as signal light) derived from the received spatial light signal into an electric signal. The light receiver 70 outputs the converted electric signal (hereinafter, referred to as a signal) to the decoder 78.

The decoder 78 acquires a signal output from the light receiver 70. The decoder 78 amplifies the acquired signal. The decoder 78 decodes the amplified signal and analyzes a signal from the communication target. The signal decoded by the decoder 78 is used for any purpose. The use of the signal decoded by the decoder 78 is not particularly limited.

For example, the decoder 78 includes a first processing circuit and a second processing circuit (not illustrated). The first processing circuit acquires a signal from the light receiver 70. The first processing circuit cuts off a signal derived from ambient light such as sunlight among the acquired signals, and selectively passes a signal of a high frequency component corresponding to a wavelength band of the spatial light signal. For example, the first processing circuit may selectively pass a signal in a wavelength band of the spatial light signal. The first processing circuit amplifies the selected signal. The first processing circuit outputs the amplified signal to the second processing circuit. The second processing circuit acquires a signal from the first processing circuit. The second processing circuit decodes the acquired signal. The second processing circuit may be configured to perform some signal processing on the decoded signal, or may be configured to output the decoded signal to an external signal processing device or the like (not illustrated). In the case of decoding a plurality of signals derived from spatial light signals from a plurality of communication targets, the second processing circuit may be configured to read the signals in a time division manner.

As described above, the receiving device according to the present example embodiment includes the light-receiving device according to any one of the first to sixth example embodiments and the decoder. The decoder decodes a signal based on the spatial light signal received by the light-receiving device. According to the receiving device of the present example embodiment, a signal based on a spatial light signal can be decoded. For example, according to the present example embodiment, a single-channel receiving device can be realized. For example, according to the present example embodiment, a multichannel receiving device can be realized by decoding a signal based on a spatial light signal in a time division manner.

### Eighth Example Embodiment

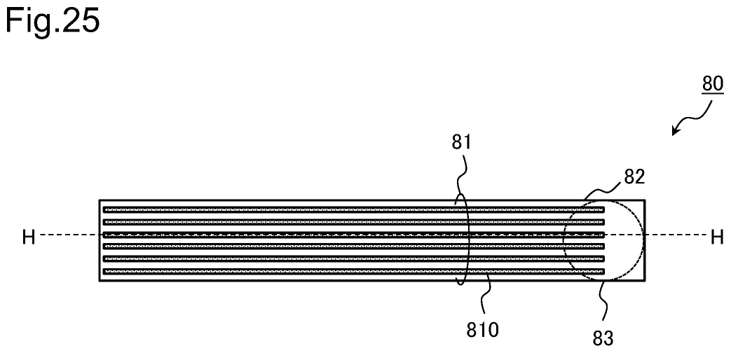

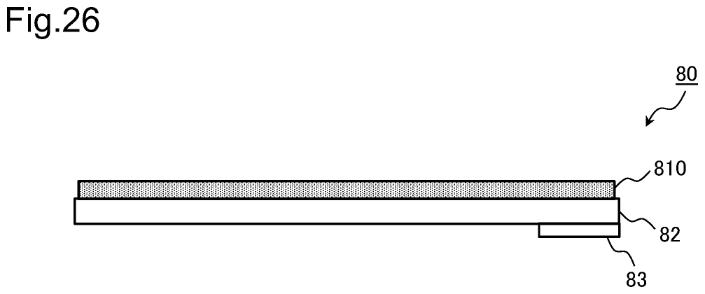

Next, a light-receiving device according to an eighth example embodiment will be described with reference to the drawings. The light-receiving device of the present example embodiment has a configuration in which the light-receiving devices of the first to sixth example embodiments are simplified. FIG. 25 is a conceptual diagram illustrating an example of a configuration of a light-receiving device 80 of the present example embodiment. FIG. 26 is a cross-sectional view of the light-receiving device 80 taken along line H-H in FIG. 25.

The light-receiving device 80 includes an optical antenna 81, a substrate 82, and a light-receiving element 83. The optical antenna 81 is formed on the first surface of the substrate 82. The optical antenna 81 receives a spatial light signal. The optical antenna 81 guides the signal light derived from the spatial light signal to the emission end along the in-plane direction of the substrate 82. The optical antenna 81 emits signal light from the emission end toward the substrate 82. The substrate 82 transmits light in a wavelength band of a spatial light signal to be received. The light-receiving element 83 is disposed with the light-receiving surface facing the second surface facing the first surface of the substrate 82. The light-receiving element 83 receives the signal light emitted from the optical antenna 81 on the light-receiving surface.

The light-receiving device according to the present example embodiment can efficiently guide signal light derived from a spatial light signal to a light-receiving element including a light-receiving portion having a small opening area capable of obtaining high-speed responsiveness. Therefore, according to the light-receiving device of the present example embodiment, the spatial light signal can be efficiently received.

This application is based upon and claims the benefit of priority from Japanese patent application No. 2021-000636, filed on Jan. 6, 2021, the disclosure of which is incorporated herein in its entirety by reference.

### REFERENCE SIGNS LIST

10, 20, 30, 40, 50, 80 light-receiving device
11, 21, 31, 41, 51, 81 optical antenna
12, 22, 32, 42, 52, 82 substrate
13, 23, 33, 43, 53, 83 light-receiving element
34 reflecting mirror
45 light pipe
56 phase shifter
57 waveguide
60 light receiver
68 support body
70 light receiver
78 decoder
110, 210, 310, 410, 510, 810 waveguide pipe
500 light-receiving unit
600 light-receiving device
700 receiving device

What is claimed is:

1. A light-receiving device comprising:
a substrate that transmits light in a wavelength band of a spatial light signal to be received;
an optical antenna that is disposed on a first surface of the substrate, receives the spatial light signal, guides signal light derived from the spatial light signal to an emission end along an in-plane direction of the substrate, and emits the signal light from the emission end toward the substrate; and
a light-receiving element that is disposed with a light-receiving surface facing a second surface facing the first surface of the substrate, and receives the signal light emitted from the optical antenna on the light-receiving surface.

2. The light-receiving device according to claim 1, comprising: a plurality of the optical antennas in which the emission end is disposed on the first surface of the substrate toward the light-receiving surface of the light-receiving element with the substrate interposed therebetween.

3. The light-receiving device according to claim 1, wherein
the optical antenna is configured by a plurality of waveguide pipes including a light-receiving portion that receives the spatial light signal, a light guide path through which the signal light derived from the spatial light signal is guided, and the emission end from which the signal light guided through the light guide path is output,
the emission ends of the plurality of waveguide pipes are disposed toward the light-receiving surface of the light-receiving element with the substrate interposed therebetween.

4. The light-receiving device according to claim 1, wherein
the optical antenna is a waveguide grating antenna.

5. The light-receiving device according to claim 1, wherein
the substrate includes a trench formed on the second surface, and
the light-receiving element is disposed at a position of the trench with the light-receiving surface facing the substrate.

6. The light-receiving device according to claim 1, further comprising
a reflecting mirror that is disposed at an end portion of the optical antenna opposite to the emission end and reflects the signal light toward the emission end.

7. The light-receiving device according to claim 1, further comprising
a light pipe that is disposed between the second surface of the substrate and the light-receiving surface of the light-receiving element and guides the signal light emitted from the emission end of the optical antenna to the light-receiving surface of the light-receiving element.

8. The light-receiving device according to claim 1, further comprising:
a phase shifter that is connected to the emission end of the optical antenna, adjusts a phase of the input signal light in such a way that a phase of the signal light is aligned at a position of the light-receiving surface of the light-receiving element, and outputs the signal light from an output end; and
a waveguide that is connected to the output end of the phase shifter, receives the signal light output from the phase shifter, and emits the input signal light toward the light-receiving surface of the light-receiving element.

9. The light-receiving device according to claim 1, wherein
a plurality of the optical antennas are disposed along a circumference of a specific circle with the light-receiving surface facing a radial direction of the specific circle.

10. A receiving device comprising:
a light-receiving device according to claim 1; and
a decoder that decodes a signal based on a spatial light signal received by the light-receiving device.
